(19) United States
(12) Patent Application Publication
(10) Pub. No.: US 2017/0104146 A1
(43) Pub. Date: Apr. 13, 2017

(54) ALLOY SYSTEM WITH ENHANCED SEEBECK COEFFICIENT AND PROCESS FOR MAKING SAME

(71) Applicant: University College Cork, National University of Ireland, Cork City (IE)

(72) Inventors: Kafil M. Razeeb, Cork City (IE); Devendraprakash Gautam, Cork City (IE)

(21) Appl. No.: 15/291,782

(22) Filed: Oct. 12, 2016

Related U.S. Application Data
(60) Provisional application No. 62/240,197, filed on Oct. 12, 2015.

(51) Int. Cl. H01L 35/28; H01L 35/16; C23C 14/16; C25D 9/04; C25D 7/12; H01L 35/34; H01L 35/18

(52) U.S. Cl. CPC H01L 35/28; H01L 35/34; H01L 35/16; H01L 35/18; C25D 9/04; C25D 7/12; C23C 14/165

(57) ABSTRACT

Provided herein are alloy systems with enhanced Seebeck coefficient and processes for making the same. An alloy system and process for improving the Seebeck coefficient of such an alloy system is disclosed. The process relates to an innovative methodology to preserve Te stoichiometry in electroplated thin films under annealing at high temperatures.

### CROSS-REFERENCE TO RELATED APPLICATIONS

This application claims the benefit of priority under 35 U.S.C. §119(e) of U.S. Provisional Patent Application No. 62/240,197, filed Oct. 12, 2015 and titled “ALLOY SYSTEM WITH ENHANCED SEEBECK COEFFICIENT AND PROCESS FOR MAKING SAME,” which is herein incorporated by reference in its entirety.

### FIELD OF THE DISCLOSURE

An improved alloy system and process for improving the Seebeck coefficient of such an alloy system.

### BACKGROUND

Thermoelectric generators (TEG) are based on the Seebeck effect where a temperature difference is converted into electrical power. This makes TEG attractive in diverse energy harvesting applications such as automobiles, waste heat recovery from industrial process, wood stoves, heating systems and wireless sensors.

The use of TEG to power the sensors instead of batteries is very promising as it eliminates the need for maintenance or replacement of the battery and is therefore cost effective. However, to employ TEG as micro-power sources, it is necessary to reduce the size of the device by employing fab process-able thin film deposition techniques (e.g. sputtering, evaporation, electroplating, etc.). But the thermoelectric efficiency of these thin film materials fabricated using physical deposition techniques is very low. Drawbacks associated with other physical methods such as need for sophisticated instrumentation; high vacuum and slow film deposition that translate into high cost of the process.

Tellurium (Te) stoichiometry in bismuth telluride alloys system plays a pivotal role in determining the thermoelectric properties of the material. Currently in the literature, Tellurium Te composition in thin films is maintained by annealing films in Te atmosphere for extended duration of time of 60 hours. This makes the process cumbersome and expensive due to the need for sophisticated instrumentation to handle toxic element (Te). Also, the literature method is incompatible with Si based fabrication process, which is a hurdle to achieve the mass production of thermoelectric devices.

### SUMMARY

It is an object to provide an improved alloy system and process for improving the Seebeck coefficient of such an alloy system.

Accordingly there is provided an alloy system and process for improving the Seebeck coefficient of such an alloy system, as set out in the appended claims.

In one embodiment there is provided an alloy system comprising Tellurium (Te) incorporated with a material using an electroplating step.

In one embodiment the material comprises bismuth.

In one embodiment the alloy system comprises at least one of carbon; alkali or alkaline earth metals.

In one embodiment the alloy system comprises a layer of material and a layer of Tellurium.

In one embodiment the alloy system comprises a first layer of material and a layer of Tellurium and a second layer of material positioned to encapsulate the layer of Tellurium between said first and second layers.

In one embodiment the alloy system comprises n-type Bismuth-Telluride based alloy.

In one embodiment the alloy system comprises p-type Bismuth-Telluride based alloy. In one embodiment the Bismuth-Telluride based alloy comprises Antimony.

In one embodiment the system comprises a binary system.

In one embodiment the system comprises a ternary system.

In one embodiment there is provided a Thermoelectric Generator (TEG) material comprising the alloy system, said system comprising Tellurium (Te) incorporated with a material using an electroplating step.

In one embodiment there is provided a Thermoelectric Cooler (TEC) material comprising the alloy system, said system comprising Tellurium (Te) incorporated with a material using an electroplating step.

In one embodiment the alloy system in the form factor of submicron wires or nanowires.

In another embodiment there is provided a process of making an alloy system comprising the step of incorporating Tellurium (Te) with a material using an electroplating step.

In one embodiment the material comprises bismuth.

In one embodiment there is provided the step of controlling the electroplating step time to tune the size and/or shape of crystals to define properties of the alloy system.

In one embodiment the electroplating step comprises a pulsed potential step.

In one embodiment there is provided an annealing step during or after the electroplating step.

In one embodiment there is provided the step of placing the Tellurium and the material in intimate contact before said electroplating step.

In one embodiment there is provided the step of encapsulating the Tellurium between a first layer of the material and second layer of the material.

In one embodiment there is provided the step of increasing the Seebeck coefficient of said alloy system.

In one embodiment the alloy system comprises at least one of carbon; alkali or alkaline earth metals.

An alternative method of Te incorporation in thin films by electroplating is described which not only maintains Te composition films after annealing but also achieves similar or better thermoelectric properties, in particular, the Seebeck coefficient like bulk material.

In one embodiment there is provided electrodeposition of multilayer in binary and ternary bismuth tellurium based alloy system (e.g. bismuth telluride, antimony telluride, bismuth antimony telluride, bismuth selenium telluride materials, etc.) are exploited to tune the size and shape of the crystals by adjusting the deposition process parameters.

Bismuth telluride alloys are known topological insulators where the surface of the material is electrically conducting. The topological properties of bismuth telluride alloys can be exploited in the electrodeposition of multilayer of the material by allowing the electrical conduction but hindering the thermal conduction.

Multilayer assembly (semiconductor-metal/different carbon allotropes-semiconductor) leads to creation of nanostructures and mesoscale in thin films on annealing which further reduces the thermal conductivity of the films.

Furthermore, carbon based allotropes (carbon nanotube, graphene) and other alkali or any other materials can be included by electrochemical co-deposition techniques to fabricate nanocomposite materials optimize/alter the composition of deposit, hierarchical structures and the thermal conductivity and in turn to enhance the thermoelectric properties of the materials.

Tellurium (Te) stoichiometry in bismuth telluride alloys system plays a pivotal role in determining the thermoelectric properties of the material. The idea of electrodeposition of multilayer is provided where a thin layer of Te is encapsulated in between bismuth telluride alloy films in a multilayer configuration. This enhances the thermoelectric properties, in particular, the Seebeck coefficient of thin films on annealing.

The Seebeck coefficient of annealed thin films with tellurium layer is about twice higher compared to films with no tellurium layer. The increment is correlated to Te composition in thin films in agreement with the findings in literature. Due to electrodeposition process the materials are in intimate contact with each other, which substantially reduces the annealing time making it cost-wise attractive.

Thus, the process herein described not only enhances the thermoelectric properties but also provides a clean and environmental friendly method to maintain tellurium stoichiometry in annealed films without the need for sophisticated instrumentation to handle the toxic element (Te), thereby making the process facile and cost effective.

The methodology can be further harvested to encapsulate: carbon, alkali or alkaline earth metals in thin films to create intimate bismuth telluride based nanocomposites on annealing for tailoring the thermal/electrical properties of the films. Thus, the process provides a tool to incorporate any elements in the bismuth telluride binary and ternary alloy system to enhance the thermoelectric properties of thin films.

In one embodiment thin films of n-type BiₓTe_{y} and p-type (Sb₁₋ₓBiₓ)₂Te₃ are synthesized at room temperature by electrodeposition at different deposition potentials on Si and glass substrates.

In one embodiment as-deposited n-type BiₓTe_{y} films comprise homogeneous porous microstructure with uniform composition. In case of p-type (SB₁₋ₓBiₓ)₂Te₃ thin films, the bath composition and the deposition potential determines both the microstructure and the composition. The surface morphology of the film varies from porous wire-like to fibrous to granular structure. The elemental compositional analysis of annealed thin films underlines the pivotal role of Te on the enhancement of Seebeck coefficient of annealed thin films.

Seebeck coefficient of the as-deposited thin films shows both positive and negative values indicating both p-and n-type charge carriers prevalent in the material. The Seebeck coefficient enhances after the annealing treatment. The optimized value of Seebeck coefficient for annealed thin films is +170 μ VK−1 for p-type material and −200 μVK⁻¹ for n-type samples.

The electrical conductivities for the as-deposited and annealed p-type thin films are respectively 1.72×10⁵ Sm⁻¹ and 1.1×10⁴ Sm⁻¹. In case of as-deposited and annealed films n-type BiₓTe_{y}, the electrical conductivity is 5.2×10⁴ Sm⁻¹ and 2.1×10⁴ Sm⁻¹ respectively.

Annealing of the as-deposited thin films has a strong impact on the Seebeck coefficient and electrical conductivity.

In another embodiment there is provided an alloy system comprising Tellurium (Te) incorporated with a material using at least one of a sputtering step, an evaporation step or an ALD step.

In another embodiment there is provided a process of making an alloy system comprising the step of incorporating Tellurium (Te) with a material using at least one sputtering, evaporation or an ALD step

### BRIEF DESCRIPTION OF THE DRAWINGS

The invention will be more clearly understood from the following description of an embodiment thereof, given by way of example only, with reference to the accompanying drawings.

FIG. 1A illustrates a SEM image of as deposited (Sb₁₋ₓBiₓ)₂Te₃. FIG. 1B illustrates a TEM image of the cross section of the as deposited film showing Te sandwich layer between SbBiTe alloy. FIG. 1C shows a SEM image of annealed (Sb₁₋ₓBiₓ)₂Te₃ film. FIG. 1D shows a SEM image of annealed (Sb₁₋ₓBiₓ)₂Te₃ film.

FIG. 2A illustrates comparison of Seebeck coefficient of (Sb₁₋ₓBiₓ)₂Te₃ thin films as-deposited films. FIG. 2B illustrates comparison of Seebeck coefficient of (Sb₁₋ₓBiₓ)₂Te₃ thin films annealed at 573 K; the films with enclosed Te layer showing high Seebeck coefficient values compared to films with no Te layer.

FIG. 3A illustrates cyclic voltammetry of electrolyte for n-type bath containing 10 mM Bi(NO₃)₃5H₂O, 15 mM Te in 1M HNO₃. FIG. 3B illustrates a SEM image of as-deposited n-type BiₓTe_{y} thin films deposited at −50 mV. FIG. 3C illustrates a SEM image of 400° C. annealed n-type BiₓTe_{y} thin films deposited at −50 mV.

FIG. 4A illustrates dependence of thermovoltage on temperature gradient (AT) for thin film annealed at 250° C., with the temperature of the cold end being shown on the curves. FIG. 4B illustrates Seebeck coefficient of n-type BiₓTe_{y} thin films as a function of temperature, with the annealing temperature being depicted on the curves.

FIG. 5 illustrates cyclic voltammetry of electrolyte for p-type bath: 5 mM Sb₂O₃, 5 mM Bi(NO₃)₃5H₂O, 15 mM Te with 0.2 M C₄H₄O₆ in 1 M HNO₃.

FIG. 6A illustrates a SEM cross-section view of as-deposited thin film. FIG. 6B illustrates a HR-STEM image of a FIB lamella of as-deposited film with sandwich Te layer. FIG. 6C illustrates a SEM cross-sectional view of annealed film. FIG. 6D illustrates aHR-STEM view of annealed films.

FIG. 7A illustrates a HR-STEM image of as-deposited p-type (Sb₁₋ₓBiₓ)₂Te₃ film. FIG. 7B illustrates a SAED pattern at point 0002 (see FIG. 7A). FIG. 7C illustrates a HR-STEM view of annealed p-type film. FIG. 7D illustrates a SAED image of annealed thin film at point 0004 (see FIG. 7C).

FIG. 8 illustrates EDX line-scan across FIB lamella of as deposited p-type (Sb₁₋ₓBiₓ)₂Te₃ thin film.

FIG. 9 illustrates EDX line-scan across FIB lamella of annealed p-type (Sb₁₋ₓBiₓ)₂Te₃ thin film.

FIG. 10 illustrates Seebeck coefficient of as-deposited and annealed p-type (Sb₁₋ₓBiₓ)₂Te₃ thin films as a function of the measured temperatures prepared using pulse sequence 5 shown in Table 2, with the annealed temperatures being denoted on the curves.

FIG. 11A illustrates X-ray diffraction patterns of p-type (Sb₁₋ₓBiₓ)₂Te₃ thin films as-deposited. FIG. 11B illustrates X-ray diffraction patterns of p-type (Sb₁₋ₓBiₓ)₂Te₃ thin films annealed at 573 K.

### DETAILED DESCRIPTION OF EMBODIMENTS

The following detailed description of embodiments presents various descriptions of specific embodiments of the invention. In this description, reference is made to the drawings in which like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

### P-Type Thin Film Synthesis Process

A process to synthesize, characterize thermoelectric materials and devices using the existing state of the art materials based on bismuth telluride is described.

The process relates to an innovative method to preserve Te stoichiometry in electroplated thin films under annealing at high temperatures. An alternative method of Te incorporation is described in thin films by electroplating which not only maintains Te composition films after annealing but also achieves similar or better thermoelectric properties, in particular, the Seebeck coefficient like bulk material. Additionally, the present process hereinbefore described is facile, cost effective, environmentally friendly and compatible with Si fabrication process.

The materials can be synthesized using a pulsed electroplating technique. In one example Silicon with 1.0 μm thermally grown SiO₂ was used as a substrate. A Ti (10 nm)/Au (20 nm) layer was sputtered on Si/SiO₂ substrate for electrodeposition of the material. The thin films were electrodeposited on the substrate using three electrodes setup in which a Cu-wire connected to substrate with Ag conducting glue acts as cathode, a platinized titanium mesh and Ag/AgCl work respectively as an anode and the reference electrode. The electroplating bath comprised of two different solutions (1) 5 mM L⁻¹ Bi(NO₃)₃.5H₂O, 10 mM L⁻¹ Sb₂O₃, 15 mM L⁻¹ Te in 1M L⁻¹ HNO₃ and 0.2M L⁻¹ tartaric acid, (2) 15 mM L⁻¹ Te in 1M L⁻¹ HNO₃ and 0.2M L⁻¹ tartaric acid. Both the electrolytic bath solutions contain 50% V/V of dimethyl sulfoxide (DMSO) and deionized H₂O.

Using a pulsed potential method, the films were prepared at room temperature as multilayers with pure Te deposited using bath solution 2 was sandwiched between the SbₓBi_{y}Te_{z} layers deposited using bath solution 1. Pure Te was deposited at a constant potential of −150 mV. The films configuration and pulse sequence appear as −250 mV, 10 ms/−80 ms, 10 ms/−50 mV, 50 ms|Te (−150 mV)|−250 mV, 10 ms/−80 ms, 10 ms/−50 mV, 50 ms.

The as-deposited films can be annealed at 573 K for 1 hour in flowing N₂ to enhance the Seebeck coefficient of (Sb₁₋ₓBiₓ)₂Te₃ thin films. The incorporation of Te as a sandwich layer will act as a Te source during annealing treatment thereby stabilizing the thermoelectric properties of thin films by maintaining Te stoichiometry and defects healing after annealing treatment. Thus, the films with encapsulated Te layer exhibit enhanced Seebeck coefficient.

### Alloy Embodiment

Bismuth telluride based alloys have been extensively investigated for TEG and cooling near room temperature applications. However, most of the commercially available materials/devices are fabricated through alloying using high temperature and pressure, physical deposition methods that require sophisticated high vacuum equipment and thereby not scalable in terms of Si based fabrication processes. Such methods are described in two publications by K. Biswas, J. He, I. D. Blum, C.-I Wu, T. P. Hogan, D. N. Seidman, V. P. Dravid and M. G. Kanatzidis, Nature, (2012), 489, 414 and P. Puneet, R. Podila, M. Karakaya, S. Zhu, J. He, T. M. Tritt, M. S. Dresselhaus and A. M. Rao, Scientific Reports, (2013), 11, 3:3212.

An important aspect of the process for Te incorporation is achieved through electroplating, which is suitable for mass scale device fabrication using conventional Si-based technology.

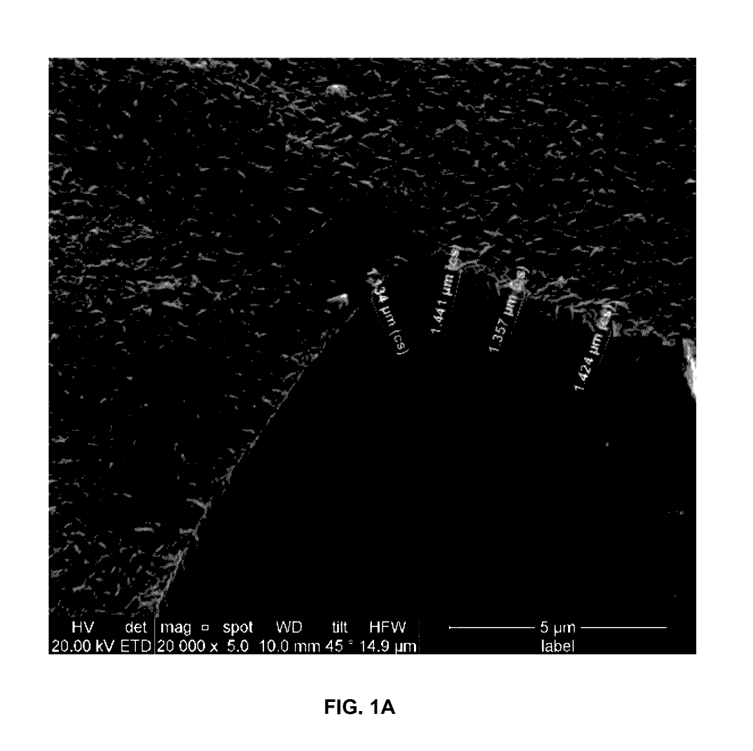

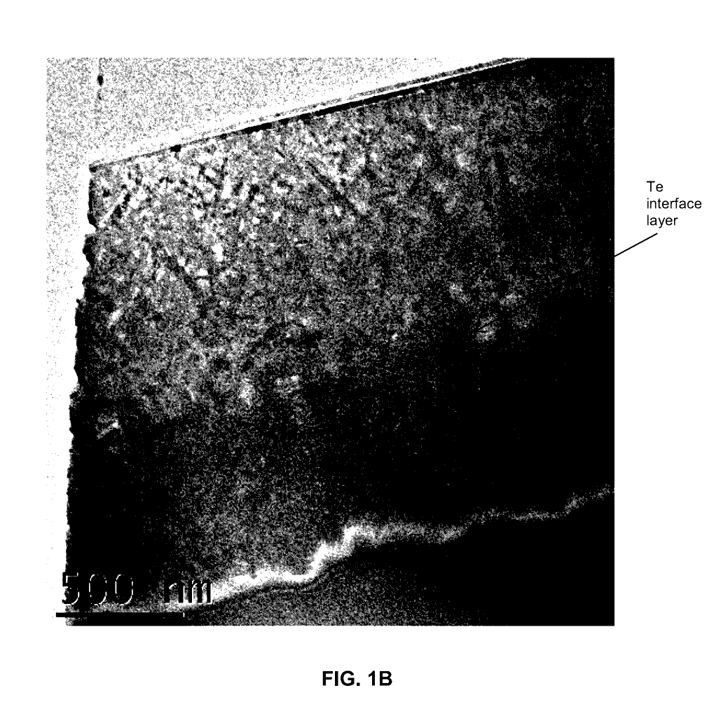

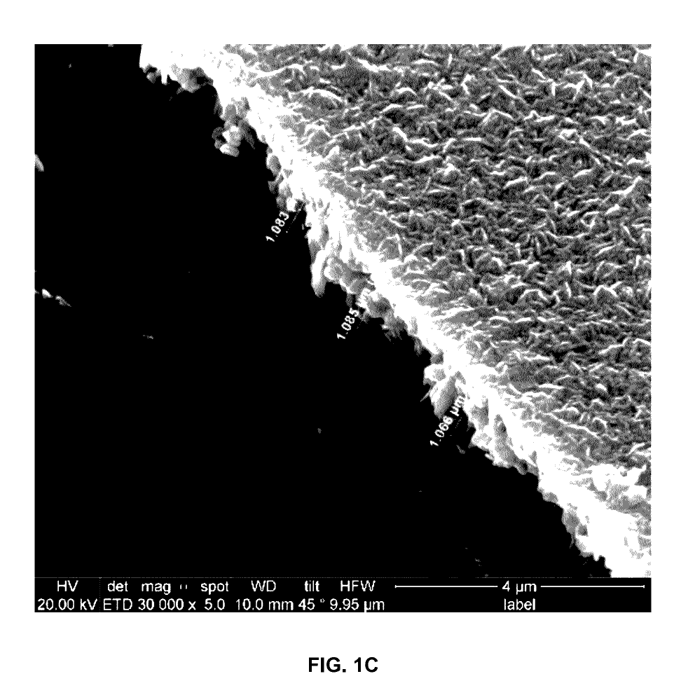

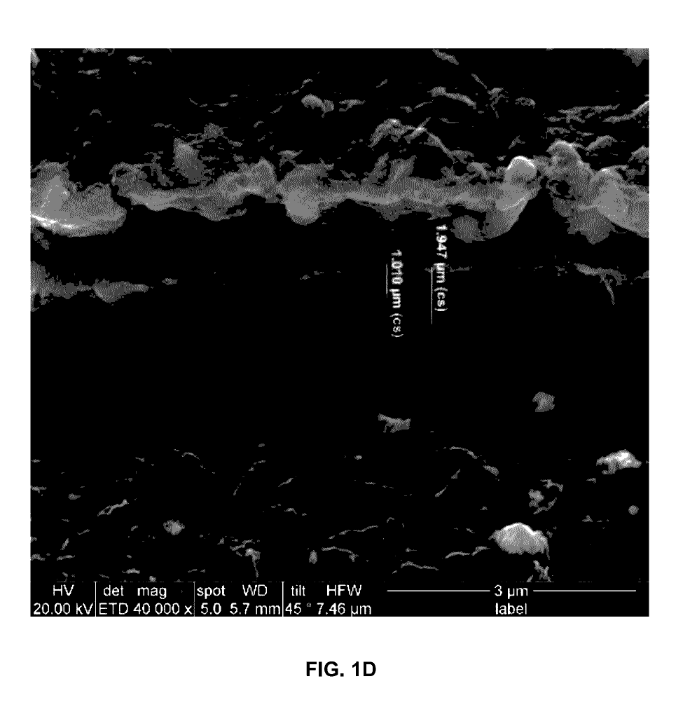

In one example (Sb₁₋ₓBiₓ)₂Te₃ thin films were prepared by electrodeposition and annealing. The Te content in the electroplated films is maintained by encapsulating a Te layer between SbBiTe alloy films. FIG. 1A showing the as deposited film on Si substrate, whereas FIG. 1B depicts a cross sectional view of the as deposited film illustrating two multilayer where Te is sandwiched between SbBiTe alloy layers. FIGS. 1C and 1D show the top and cross sectional views of the annealed film, namely (Sb₁₋ₓBiₓ)₂Te₃ film.

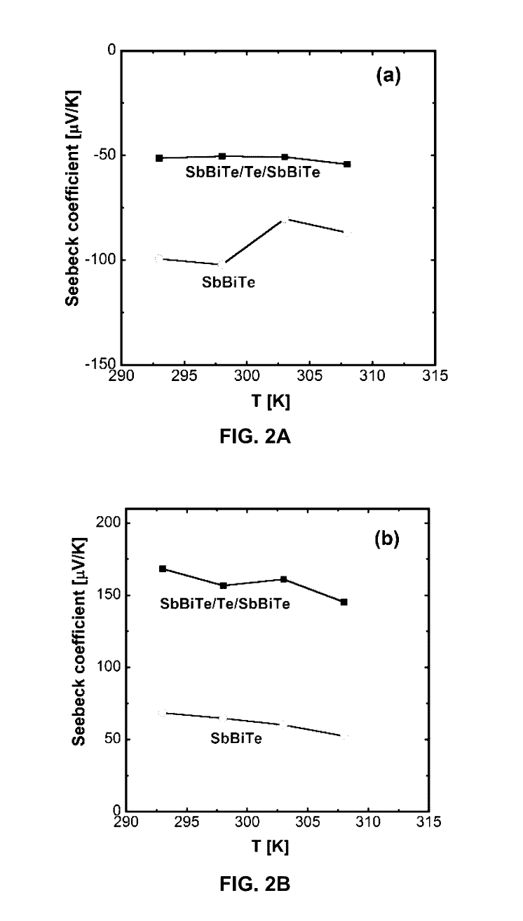

FIGS. 2A and 2B illustrate a comparison of Seebeck coefficient of (Sb₁₋ₓBiₓ)₂Te₃ thin films as-deposited films (FIG. 2A) and annealed at 573 K (FIG. 2B). The films with enclosed Te layer shows high Seebeck coefficient values compared to films with no Te layer. The Seebeck coefficient of (Sb₁₋ₓBiₓ)₂Te₃ thin films with and without Te layer is compared in FIGS. 2A and 2B. Seebeck coefficient of the as-deposited films (FIG. 2A) shows negative values for both configurations and becomes positive after annealing (FIG. 2B). However, the enhancement in Seebeck coefficient is strongly evident in case of films with sandwich Te layer. The Seebeck coefficient of annealed thin film with tellurium layer is about 170 μVK⁻¹, which is twice higher compared to films with no tellurium layer.

The advantages of Te incorporation are:
(a) Huge reduction in annealing time due to intimate contact of electroplated Te with the SbBiTe alloy films.
(b) Cost effective, no requirement of specialized instrument for handling toxic Te element, compatible with Si-based process and environmentally friendly.
   Embodiment—N-Type BiₓTe_{y} films

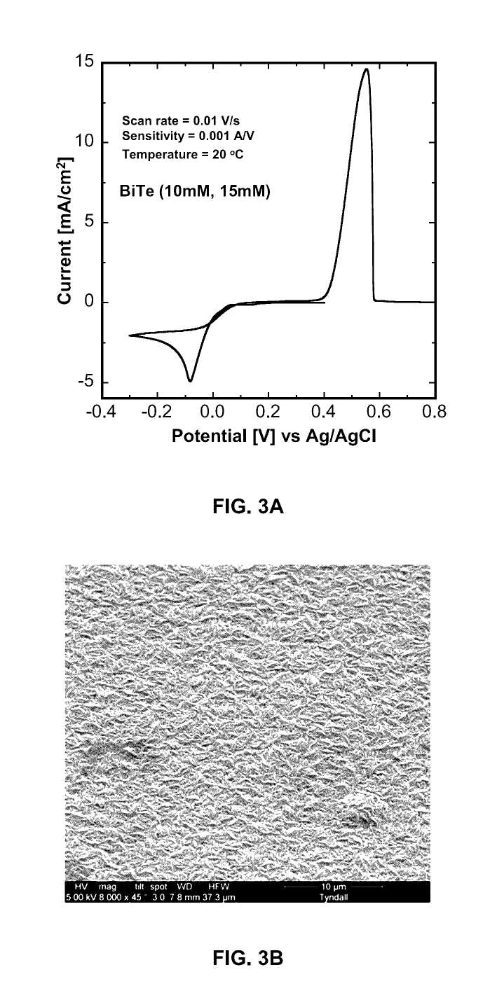

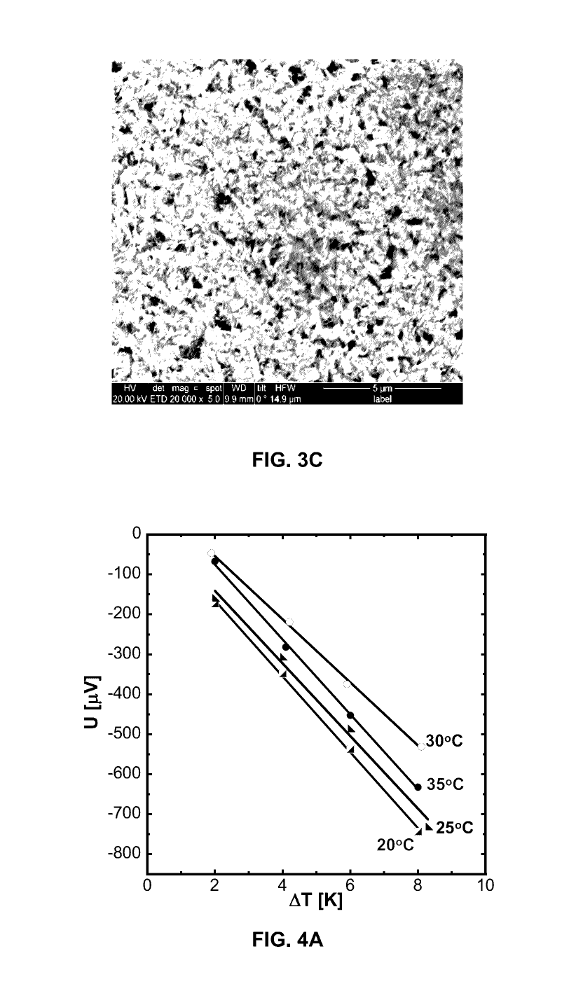

In one embodiment materials were deposited using electrodeposition technique at room temperature. In order to study the effect of the bath (electrolyte) composition on the deposited film, several bath compositions were prepared. A typical composition for n-type bath is shown in Table 1. Before the films were deposited, the baths were studied using cyclic voltammetry (CV). FIG. 3A shows the typical CV of the electrolyte used for the deposition of n-type BiₓTe_{y} films. For n-type material single reduction peak was observed and films were prepared by applying a potential of −50 mV. The structural studies reveal that the as-deposited n-type films are smooth, fibrous and porous (see FIG. 3B), which is in agreement with the published reports in the literature. The growth rate for n-type film is about 1.4 μm/h. Thin films were annealed to improve its microstructure as well as the electrical and thermal properties. After annealing the films in N₂ atmosphere at different temperatures (250° C., 300° C., 400° C.), the microstructure exhibits porous and granular structure as depicted in FIG. 3C. Such a porous and granular microstructure is beneficial for better thermoelectric materials as it decreases thermal conductivity without much impact on the electrical conductivity and Seebeck coefficient. There is no observable change in the composition of the films measured by EDX (energy dispersive X-ray spectroscopy) after annealing.

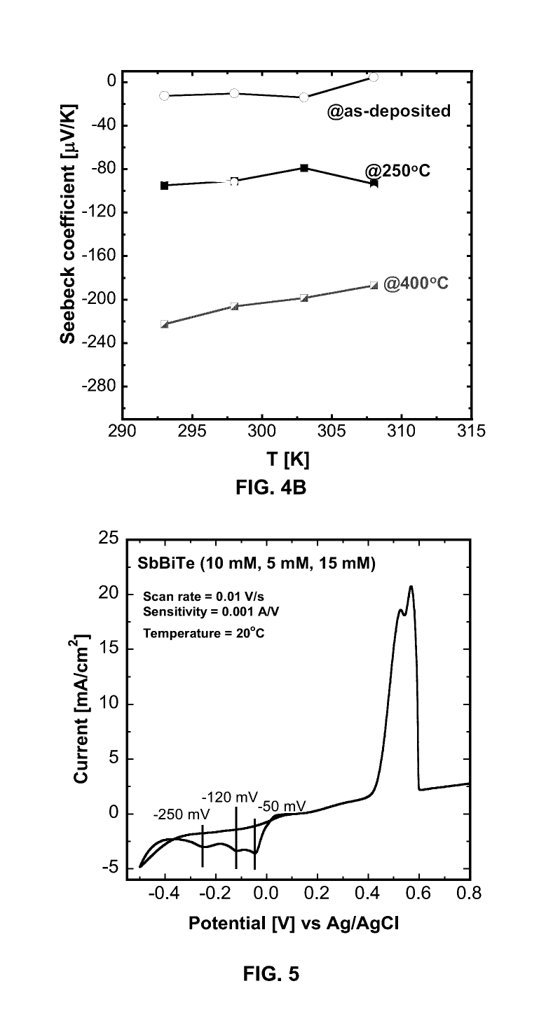

Seebeck coefficient was measured by applying a temperature gradient across the thin films. The dependence of thermovoltage on the temperature gradient exhibits a linear behaviour as depicted in FIG. 4A for film annealed at 250° C. The slope of the curve represents the Seebeck coefficient that is plotted as a function of temperature for the as-deposited and annealed thin films (see FIG. 4B). The Seebeck coefficients are negative, underlining the nature of the charge carriers in the materials. The coefficient of the films increases with the annealing temperature suggesting the film becomes granular and passivated substantiating the microstructural observation. The observations on Seebeck coefficient for n-type BiₓTe_{y} films are in good agreement with the literature and the properties of the optimized n-type BiₓTe_{y} films are shown in Table 3 below.

Embodiment—P-Type (Sb₁₋ₓBiₓ) ₂Te₃

In contrast, the experimental observations to obtain p-type (Sb₁₋ₓBiₓ)₂Te₃ thin films did not reflect the findings published in the literature. Four different bath compositions were developed for the electrodeposition of the films. Table 1 shows a typical bath composition, which resulted in a p-type material after annealing.

TABLE 1
Studied bath composition for the synthesis of p-type (Sb₁₋ₓBiₓ)₂Te₃

| | | | Te | | Tartaric | |
|---|---|---|---|---|---|---|
| Compo- | Bi(NO₃)₃•5H₂O | Sb₂O₃ | powder | HNO₃ | Acid | |
| sition | (M) | (M) | (M) | (M) | (M) | DMSO |
| p-type | 0.005 | 0.010 | 0.015 | 1.0 | 0.2 | 50% |
| Bath | | | | | | V/V |
| n-type | 0.010 | 0.0 | 0.015 | 1.0 | 0.0 | 50% |
| Bath | | | | | | V/V |

FIG. 5 shows the CV of the bath solution (see p-type bath, Table 1) used for the deposition of p-type (Sb₁₋ₓBiₓ)₂Te₃ films. As illustrated in FIG. 5, three different reduction peaks were observed that are associated with the reduction potentials of Bi, Sb and Te. The p-type films were prepared under both the constant and pulsed potential. This allowed us to synthesize films with varied composition, morphology and microstructure. The reduction potential was varied from −50 mV to −250 mV and different pulse parameters were selected to achieve a particular composition of thin film (see Table 2). The optimized pulse sequence that gave the best p-type material in the present work is shown in Table 2 (see pulse sequence 5). In order to maintain Te stoichiometry in thin films after annealing, pure Te (15 mM Te in 1 M HNO₃, 0.2 M Tartaric acid, 50% V/V DMSO) deposited at −150 mV was sandwich between SbₓBi_{y}Te_{z} layers (see Table 2 and pulse 5).

TABLE 2
p-type (Sb₁₋ₓBiₓ)₂Te₃ film synthesized by pulsed electroplating
using bath solution 4 and pure Te (15 mM) at −150 mV.

| No. | Pulse sequence |
|---|---|
| 1 | −220 mV, 10 ms/0 mV, 100 ms |
| 2 | −220 mV, 10 ms/−80 ms, 10 ms/0 mV, 100 ms |
| 3 | −250 mV, 10 ms/−80 ms, 10 ms/−50 mV, 50 ms |
| 4 | −250 mV, 10 ms/−80 ms, 10 ms/−50 mV, 50 ms \| Te (−150 mV) |
| 5 | −250 mV, 10 ms/−80 ms, 10 ms/−50 mV, 50 ms \| Te (−150 mV) |
| | \| −250 mV, 10 ms/−80 ms, 10 ms/−50 mV, 50 ms |
| 6 | Te(−150 mV) \| −250 mV, 10 ms/−80 ms, 10 ms/−50 mV, |
| | 50 ms \| Te (−150 mV) |
| 7 | −250 mV, 10 ms/−80 ms, 10 ms/−50 mV, 50 ms \| Te (−150 mV) |
| | (8 layers) |

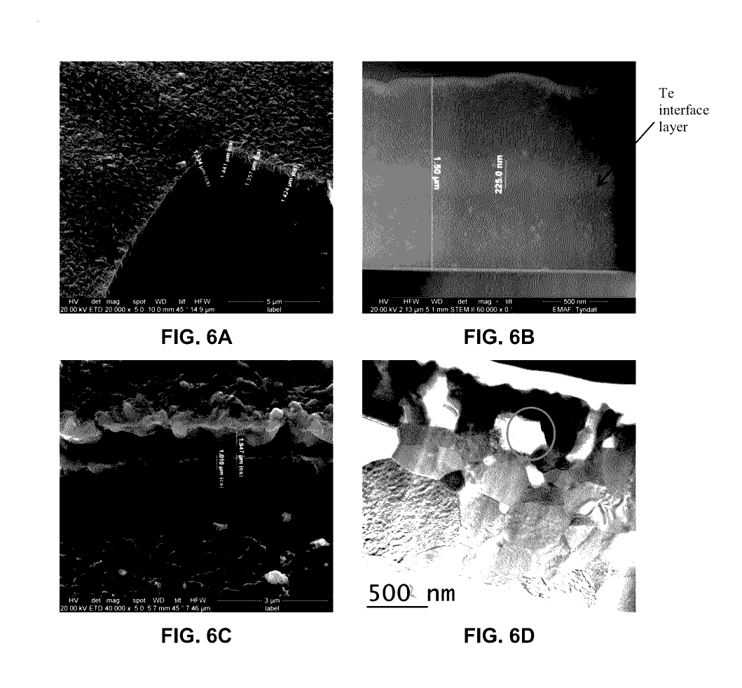

The growth rate for p-type film is about 0.9 μm/h. FIG. 6A shows the microstructure of the as-deposited thin films with Te sandwich between SbₓBi_{y}Te_{z} layers on Si substrate. The surface morphology of the thin films is porous with wire-like structure. FIG. 6B depicts the HR-STEM cross-sectional view of the lamella cut from the as-deposited film.

It is clearly evident that the Te layer of about 225 nm is encapsulated between the SbₓBi_{y}Te_{z} layers with the overall film thickness of about 1.3-1.5 μm. The lower SbₓBi_{y}Te_{z} layer structure shows a preferred growth direction. The annealing resulted in a granular and porous microstructure of thin films with average film thickness of about 1.0-1.9 μm (see FIG. 6C). It should be mentioned that with increasing annealing temperature there is grain growth and formation of layered structure at some places in the film. This layered structure can be due to the evaporation and condensation of the material within the thin films. FIG. 6D illustrates a HR-STEM cross-sectional image of the annealed sample. The structure of annealed films has a porous and granular morphology with grain size in the range of 100-500 nm indicating a polycrystalline material as shown in FIG. 6D. Such a porous microstructure with different grain size can act as a good thermoelectric material because their thermal conductivity can be suppressed without considerable affecting the electrical conductivity and Seebeck coefficient.

The observation of large holes (see FIG. 6D) can be due to the removal of material during the focussed ion beam (FIB) milling process. A closer view (see marked region in FIG. 6D) reveals that the big crystal consists of finer grains, which can scatter the phonons effectively.

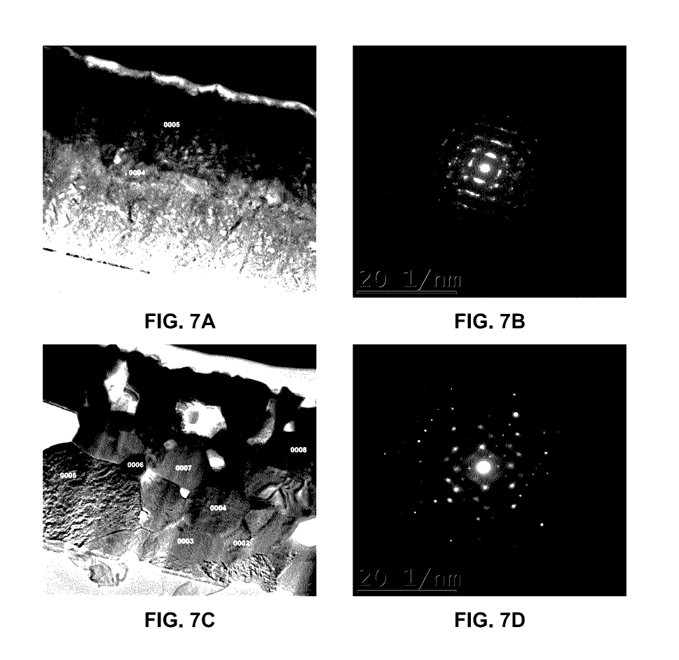

FIGS. 7A-7D illustrate the selected area electron diffraction (SAED) patterns of the lamella of the as-deposited and annealed film with Te encapsulated layer. FIG. 7B depict SAED image at point 0002 (see FIG. 7A) for the as-deposited films. The diffraction pattern at 0002 (FIG. 7B) indicates that the material is polycrystalline with a preferred orientation along [015] and [110] direction having a d-spacing of 0.322 nm and 0.219 nm, respectively. However, the intensity for [015] is stronger compared to the [110] plane (see FIG. 7B). The SAED pattern taken at point 0005 (see FIG. 7C) on the FIB lamella of annealed film is shown in FIG. 7D. The pattern demonstrates the materials are crystalline with orientation along [110] and [015]. Even though both orientations are present in the annealed samples, the intensity of [110] is high compared to [015] plane.

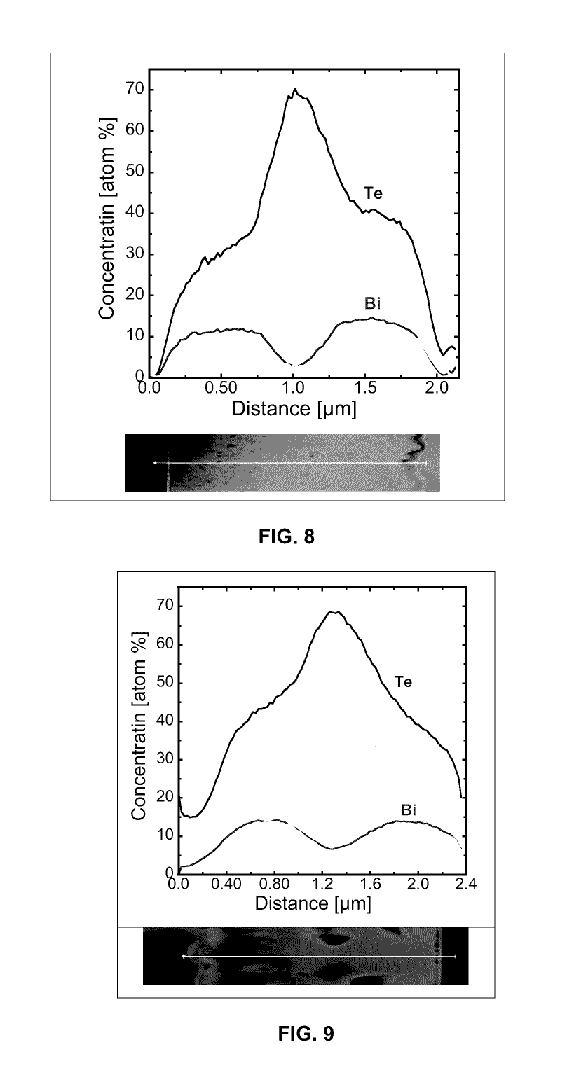

FIG. 8 illustrates the EDX line scan across the as-deposited thin film lamella. The spectrum shows a steep increment in Te content particularly at a distance of 0.9-1.2 μm indicating the presence of sandwiched Te layer in the sample. It is notable that the concentration of Sb and Bi in this distance range is nearly negligible.

The EDX line scan across the annealed thin film lamella is illustrated in FIG. 9. As observed from the spectrum there is still Te rich region, which has narrowed after annealing. However, the intermediate Te layer has diffused into SbₓBi_{y}Te_{z} regions. This observation is in agreement with the literature reports underlining that Te evaporates from SbBiTe alloy films during annealing process. Thus, it is extremely crucial to maintain Te content in thin films during the annealing process, which eventually determines the thermoelectric properties, in particular the Seebeck coefficient of the material.

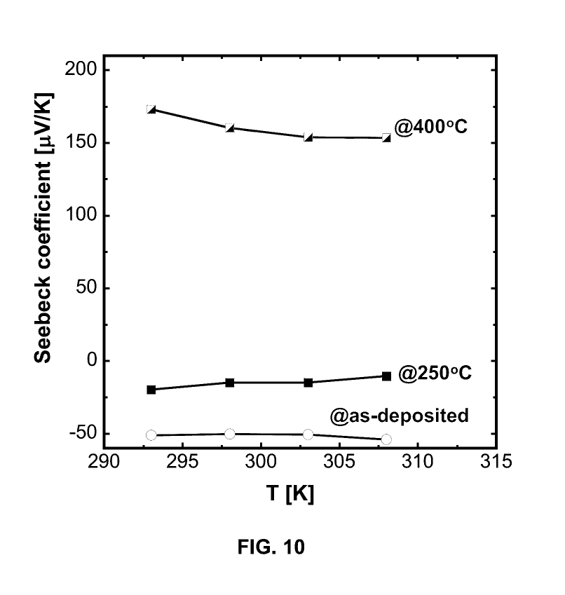

Seebeck coefficient of the as-deposited films shows negative values as illustrated in FIG. 10. The values of Seebeck coefficient becomes positive and increase after annealing the films at various temperatures. The film prepared using pulse sequence 5 shown in Table 2 shows the best Seebeck coefficient values, in particular, as long as the variation of the Seebeck coefficient with temperature is concerned. The trend is relatively flat when the measurement temperature was varied with a standard deviation of ±10%.As demonstrated above from the elemental chemical analysis that this enhancement in the Seebeck coefficient in annealed films is due to the Te layer sandwich between SbₓBi_{y}Te_{z}, which maintains the Te stoichiometry in annealed thin films. Thus, the advantages of Te incorporation are:
(a) Huge reduction in annealing time due to intimate contact of electroplated Te with the SbBiTe alloy films.
(b) Cost effective, no requirement of specialized instrument for handling toxic Te element, and thereby compatible with Si-based process and environmentally friendly.

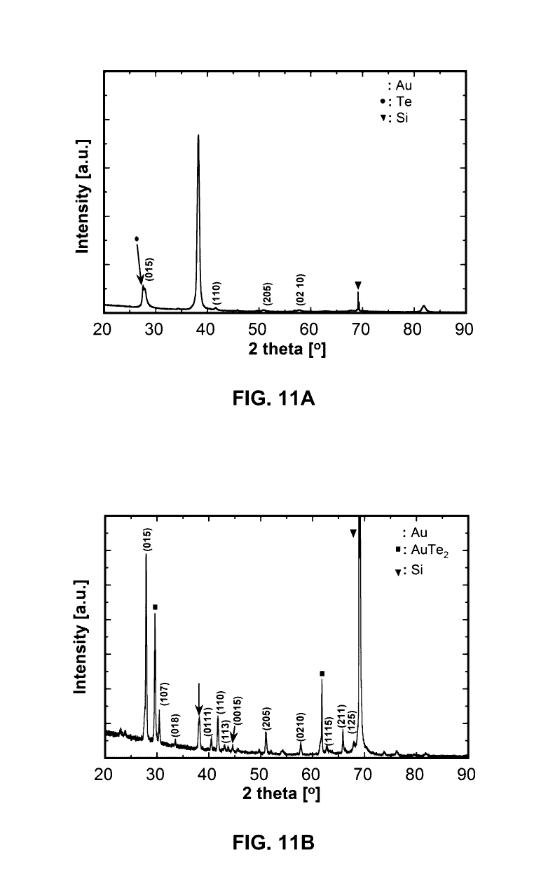

FIG. 11 illustrates X-ray diffraction patterns of as-deposited p-type (Sb₁₋ₓBiₓ)₂Te₃ films (FIG. 11A) and annealed at 573 K (FIG. 11B). The patterns reveal that the film become polycrystalline on annealing. Both the crystallinity and the crystallite size are enhanced on annealing. Additional peaks pertaining to Au and AuTe₂ are also observed in the patterns.

Finally, the best values of the Seebeck coefficient obtained for the n- and p-type films are shown in Table 3.

TABLE 3
Seebeck coefficient for n-and p-type
films in comparison to the literature

| Sample | Seebeck coefficient [μVK⁻¹]-present work |
|---|---|
| n-BiₓTe_{y} | −200 |
| p-(Sb₁₋ₓBiₓ)₂Te₃ | +170 |

It will be appreciated that the process hereinbefore described can be commercially applied to any thin film technology, where it is required to maintain the composition of films for enhanced thermoelectric properties or any functional properties optimization. This becomes especially critical when the annealing treatment is required and the volatility of a component of the film is an issue during annealing. The present innovative method of encapsulating Te in the multilayer configuration reduces the cost of the Te incorporation which is currently done in a conventional way of annealing the material in Te atmosphere.

### CONCLUSION

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail. Thus, although this invention has been described in terms of certain embodiments, other embodiments that are apparent to those of ordinary skill in the art, including embodiments that do not provide all of the features and advantages set forth herein, are also within the scope of this invention. Moreover, the various embodiments described above can be combined to provide further embodiments. In addition, certain features shown in the context of one embodiment can be incorporated into other embodiments as well. Accordingly, the scope of the present invention is defined only by reference to the appended claims.

What is claimed is:

1. An alloy system comprising Tellurium (Te) incorporated with a material having an enhanced Seebeck coefficient.

2. The alloy system of claim 1 wherein the material comprises bismuth.

3. The alloy system of claim 1 wherein the material is incorporated with Tellurium using an electroplating step.

4. The alloy system of claim 1 wherein the alloy system comprises at least one of carbon; alkali or alkaline earth metals.

5. The alloy system of claim 1 wherein the alloy system comprises a layer of material and a layer of Tellurium.

6. The alloy system of claim 1 wherein the alloy system comprises a first layer of material and a layer of Tellurium and a second layer of material positioned to encapsulate the layer of Tellurium between said first and second layers.

7. The alloy system of claim 1 wherein the alloy system comprises n-type Bismuth-Telluride based alloy or p-type Bismuth-Telluride based alloy.

8. The alloy system of claim 1 wherein the system comprises a binary system or a ternary system.

9. The alloy system of claim 1 wherein the alloy system is in the form factor of submicron wires or nanowires.

10. A Thermoelectric Generator (TEG) material comprising the alloy system of claim 1.

11. A thermoelectric cooler (TEC) material comprising the alloy system of claim 1.

12. A process of making an alloy system comprising the step of incorporating Tellurium (Te) with a material using an electroplating step.

13. The process of claim 12 wherein the material comprises bismuth.

14. The process of claim 12 comprising the step of controlling the electroplating step time to tune the size and/or shape of crystals to define properties of the alloy system.

15. The process of claim 12 wherein the electroplating step comprises a pulsed potential step.

16. The process of claim 12 comprising an annealing step during or after the electroplating step.

17. The process of claim 12 comprising the step of placing the Tellurium and the material in intimate contact before said electroplating step.

18. The process of claim 12 comprising the step of encapsulating the Tellurium between a first layer of the material and second layer of the material.

19. The process of claim 12 comprising the step of increasing the Seebeck coefficient of said alloy system.

20. The process of claim 12 wherein the alloy system comprises at least one of carbon; alkali or alkaline earth metals.
